(19) United States
(12) Patent Application Publication
(10) Pub. No.: US 2016/0066474 A1
(43) Pub. Date: Mar. 3, 2016

(54) HOUSING CAPABLE OF DISSIPATING HEAT THEREIN

(71) Applicants: LITE-ON ELECTRONICS (GUANGZHOU) LIMITED, GUANGZHOU (CN); LITE-ON TECHNOLOGY CORP., TAIPEI (TW)

(72) Inventor: PING-KUN FU, TAIPEI (TW)

(21) Appl. No.: 14/803,226

(22) Filed: Jul. 20, 2015

(30) Foreign Application Priority Data
Sep. 3, 2014 (CN) 201410446258.4

(51) Int. Cl. H05K 7/20

(52) U.S. Cl. CPC H05K 7/20409

(57) ABSTRACT

A housing is capable of dissipating heat, and includes a housing body constituted of a plurality of walls, an orientation detecting unit for detecting orientation of the housing body and generating a detection signal for indicating the orientation of the housing body, a fan mounted at an opening in one of the walls, and a controller coupled to the orientation detecting unit and the fan. The controller is configured to determine which one of the walls is on the top of the housing body according to the detection signal received from the orientation detecting unit, and to control operation of the fan for causing an upward air flow within the housing body towards the wall on the top of the housing body.

### CROSS-REFERENCE TO RELATED APPLICATION

This application claims priority of Chinese Patent Application No. 201410446258.4, filed on Sep. 3, 2014.

### FIELD

The disclosure relates to a housing, and more particularly to a housing capable of dissipating heat therein.

### BACKGROUND

A conventional housing of a desktop computer is generally equipped with a fan in order to dissipate heat in the conventional housing. The conventional housing may be further equipped with an electronic circuit to control rotational speed of the fan according to temperatures inside the conventional housing. However, the orientation of the fan is changed along with change in orientation of the conventional housing, and in some instances, air intake of the fan may be adversely affected so that air convection inside the conventional housing is reduced. Hence, upward flow of hot air within the conventional housing is affected, and it is difficult to dissipate the heat in the conventional housing to the outside, reducing heat dissipation efficiency.

Besides, the electronic circuit of the conventional housing cannot adjust operation modes of the fan (e.g., exhaustion and intake) automatically with respect to the orientation of the conventional housing.

### SUMMARY

Therefore, an object of the disclosure is to provide a housing to meliorate heat dissipation efficiency.

According to the disclosure, the housing is capable of dissipating heat therein, and includes a housing body, an orientation detecting unit, a fan and a controller.

The housing body is constituted of a plurality of walls, one of which is formed with an opening. The orientation detecting unit is configured for detecting an orientation of the housing body and for generating a detection signal that indicates the orientation of the housing body. The fan is mounted to said one of the walls at the opening. The controller is coupled to the orientation detecting unit and the fan, and is configured to determine which one of the walls is on the top of the housing body according to the detection signal received from the orientation detecting unit, and to control operation of the fan for causing an upward airflow within the housing body toward one of the walls that is on the top of the housing body.

### BRIEF DESCRIPTION OF THE DRAWINGS

Other features and advantages of the disclosure will become apparent in the following detailed description of the embodiments with reference to the accompanying drawings, of which:

FIG. 1 is a schematic perspective view of a first embodiment of the housing according to the disclosure;

FIG. 2 is a schematic perspective view of a first variation of the first embodiment of the housing according to the disclosure;

FIG. 3 is a schematic perspective view of a second variation of the first embodiment of the housing according to the disclosure; and

FIG. 4 is a schematic perspective view of a second embodiment of the housing according to the disclosure.

### DETAILED DESCRIPTION

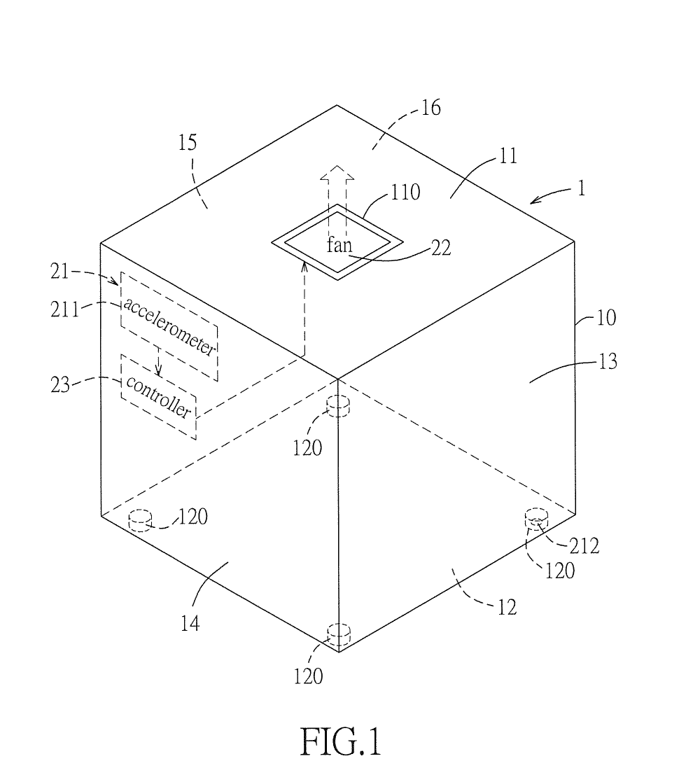

Referring to FIG. 1, the first embodiment of a housing 1 according to the disclosure is capable of dissipating heat therein, and is configured to contain electronic components of, for example, a desktop computer, a projector, etc. The housing 1 includes a housing body 10 constituted of a plurality of walls, an orientation detecting unit 21, a fan 22, and a controller 23 coupled to the orientation detecting unit 21 and the fan 22. In this embodiment, the housing body 10 is a cube, and is constituted of six walls 11-16, one of which (in particular, the wall 11) is formed with an opening 110.

The orientation detecting unit 21 is configured to detect an orientation of the housing body 10, and to generate a detection signal that indicates the orientation of the housing body 10. The orientation detecting unit 21 includes an accelerometer 211 and a switch (e.g., a push-button) 212. In other embodiments, the orientation detecting unit 21 may include only one of the accelerometer 211 and the switch 212. The switch 212 can be integrated with one of a plurality of foot cushions 120 mounted on one of the walls 11-16 of the housing body 10, specifically the wall 12 in this exemplary embodiment. The fan 22 is mounted on the wall 11 and at the opening 110. The controller 23 is configured to receive the detection signal from the orientation detecting unit 21, and to determine which one of the walls 11-16 is currently on the top of the housing body 10 according to the detection signal. The controller 23 is further configured to control operations of the fan 22 for causing an upward airflow within the housing body 10 toward said one of the walls 11-16 that is on the top (e.g., the wall 11 in FIG. 1), so that heat produced by the electronic components disposed in the housing 1 can be transmitted upwardly with the upward airflow.

For example, it is assumed that a default orientation for the housing body 10 is the orientation shown in FIG. 1, in which the wall 11 is on the top and the foot cushions 120 mounted on the wall 12 (opposite to the wall 11) contact a surface (not shown). When the housing body 10 is kept at the default orientation, the accelerometer 211 generates a steady acceleration signal indicating no change in direction. Further, since the foot cushions 120 contact the surface, the switch 212 integrated with one of the foot cushions 120 is pressed and generates a switch signal. Therefore, the controller 23 determines that the wall 11 of the housing body 10, which is provided with the fan 22, is on the top according to at least one of the acceleration signal and the switch signal that serves as the detection signal from the orientation detecting unit 21. In the case that the orientation detecting unit 21 only includes one of the accelerometer 211 and the switch 212, a corresponding one of the acceleration signal and the switch signal serves as the detection signal.

In order to encourage heat convection in the housing 1, the controller 23 controls the fan 22 to operate in an exhausting mode for causing the upward airflow within the housing body 10 toward the wall 11 and for exhausting hot air in the housing body 10 through the opening 110 and the fan 22. Thus, as the hot air is exhausted, heat produced by the electronic components is dissipated out of the housing 1. At the same time, cold air flows into the housing 1 through slits or holes of the housing body 10 for cooling the electronic components.

When the housing body 10 is rotated, for example, by 90 degrees from the default orientation to a different orientation, the wall 11 is placed to the lateral side and the switch 212 underneath the wall 12 is not pressed anymore. Therefore, the switch 212 would not generate the switch signal, and, the acceleration signal generated by the accelerometer 211 changes corresponding to the change of the orientation of the housing body 10 and serves as the detection signal sent to the controller 23. Accordingly, the controller 23 is able to determine which one of the walls 11-16 is on top of the housing body 10.

Under this circumstance, for promoting heat convection inside the housing body 10, the controller 23 controls the fan 22 to be operated in an intake mode for drawing air into the housing body 10 through the opening 110 to cause the upward airflow within the housing body 10 toward a top one of the walls 11-16 which is on the top. Therefore, hot air flow caused by heat convection in the housing body 10 and natural convection would rise towards the top one of the walls 11-16 and flow out through holes or slits on the housing body 10.

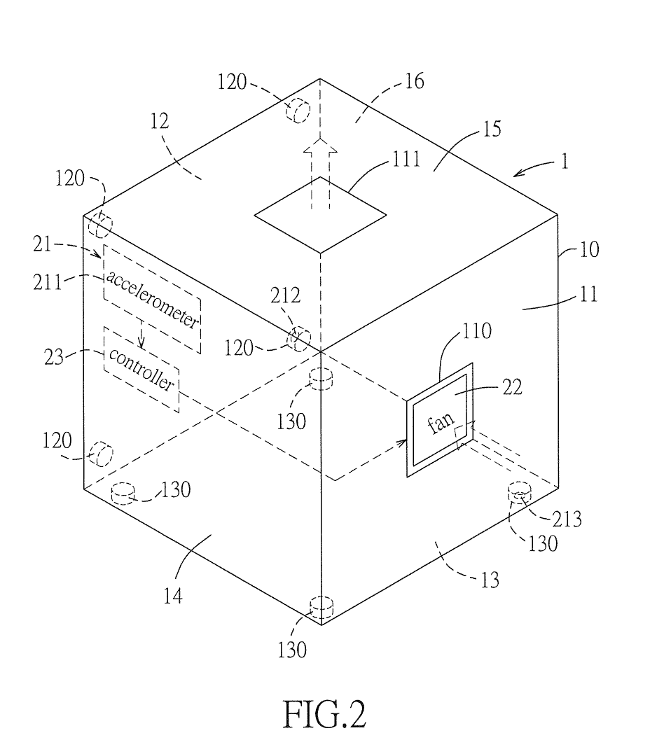

FIG. 2 illustrates a first variation of the first embodiment of the housing 1 according to the disclosure.

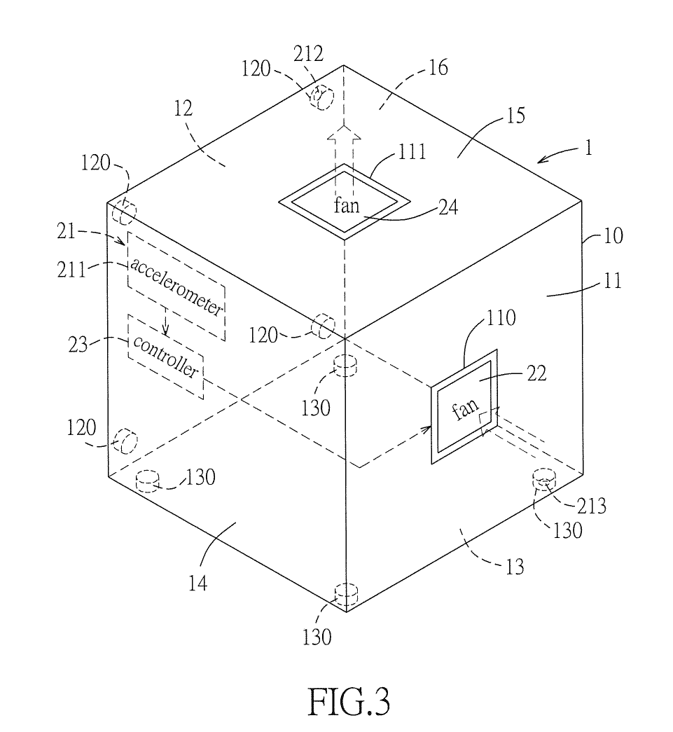

In this variation, the orientation detecting unit 21 further includes another switch 213 installed at one of a plurality of foot cushions 130 underneath the wall 13. In the orientation where the switch 212 is not pressed as shown in FIG. 2, the switch 213 installed on the wall 13 is, and produces a switch signal serving as the detection signal sent to the controller 23. Therefore, the controller 23 determines that the wall 15 opposite to the wall 13 is at the top according to the detection signal from the switch 213. In addition, in order to enhance heat dissipation, the wall 15 opposite to the wall 13 is formed with another opening 111, through which the hot air is exhausted. Furthermore, FIG. 3 illustrates a second variation of the first embodiment of the housing 1 according to the disclosure similar to the first variation. In this variation, the housing 1 further includes another fan 24 coupled to the controller 23 and mounted to the wall 15 at the opening 111. In the orientation as shown in FIG. 3, the fan 24 is controlled by the controller 23 to operate in the exhausting mode for promoting the upward airflow within the housing body 10 and for exhausting the hot air through the opening 111 in the wall 15, while the fan 22 is controlled by the controller 23 to operate in the intake mode for drawing air into the housing body 10 through the opening 110. Accordingly, heat convection in the housing body 10 is enhanced by the fan 22 operating in the intake mode to draw in cold air and the fan 24 operating in the exhausting mode to exhaust hot air. The controller 23 could also raise the rotational speed of the fans 22 and 24 for further enhancing the heat convection.

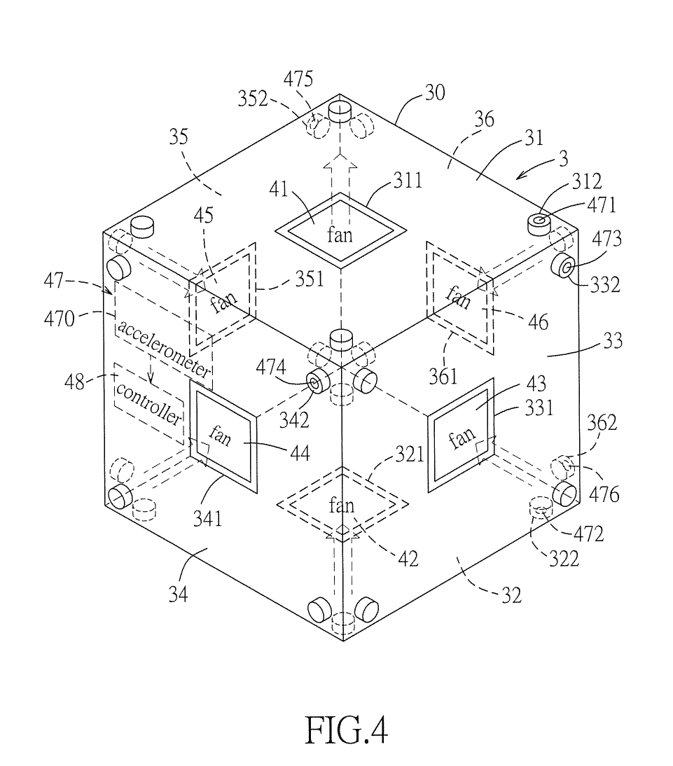

FIG. 4 is the second embodiment of the housing 3 according to this disclosure. In this embodiment, the walls 31-36 of the housing body 30 of the housing 3 are formed with openings 311, 321, 331, 341, 351, 361, respectively, and the housing 3 includes a plurality of fans 41-46. Each of the fans 41-46 is mounted on a respective one of the walls 31-36 at a corresponding opening 311, 321, 331, 341, 351, 361. The orientation detecting unit 47 includes an accelerometer 470, and a plurality of switches 471-476, each of which is installed at one of a plurality of foot cushions 312, 322, 332, 342, 352 or 362 on a corresponding one of the walls 31-36. When one of the walls 31-36 is in contact with a surface, the corresponding one of the switches 471-476 on said one of the walls 31-36 is pressed and transmits a switch signal, which cooperates with the acceleration signal to serve as the detection signal, to the controller 48. For instance, when the wall 32 with the switch 472 is in contact with a surface, the switch 472 is pressed and sends out the switch signal to the controller 48 which then determines that the wall 31 opposite to the wall 32 is on the top of the housing body 30 according to the switch signal from the switch 472. The controller 48 thus controls the fan 41 on the wall 31 to operate in the exhausting mode and all (or one) of the rest of the fans 42-46 on the wall 32-36, respectively, to operate in the intake mode. As a result, heat convection is promoted in the housing body 30, causing efficient exhaustion of the hot air in the housing body 30 through the opening 311 in the wall 31.

In conclusion, by virtue of the orientation detecting unit 21, 47, the controller 23, 48 can determine which one of the walls 11-16, 31-36 is on the top of housing body 10, 30. The controller 23, 48 then accordingly controls the operation mode(s) of the fan(s) 22, 23, 41-46, and adjusts the rotational speed of the fan(s) 22, 23, 41-46 for heat dissipation. When the orientation of the housing body 10, 30 is altered, heat convection is not affected due to the appropriate operation mode (s) of the fan(s) 22, 23, 41-46.

While the disclosure has been described in connection with what are considered the exemplary embodiments, it is understood that this disclosure is not limited to the disclosed embodiments but is intended to cover various arrangements included within the spirit and scope of the broadest interpretation so as to encompass all such modifications and equivalent arrangements.

What is claimed is:

1. A housing capable of dissipating heat therein, said housing comprising:
a housing body constituted of a plurality of walls, one of which is formed with an opening;
an orientation detecting unit for detecting an orientation of said housing body and generating a detection signal that indicates the orientation of said housing body;
a fan mounted to said one of said walls at said opening; and
a controller coupled to said orientation detecting unit and said fan, and configured to determine which one of said walls is on the top of said housing body according to the detection signal received from said orientation detecting unit, and to control operation of said fan for causing an upward airflow within said housing body toward one of said walls that is on the top of said housing body.

2. The housing as claimed in claim 1, wherein, when said controller determines that said one of said walls which is provided with said fan is on the top of said housing body, said controller is configured to control said fan to operate in an exhausting mode for causing the upward airflow within said housing body toward said one of said walls and for exhausting air in said housing body through said opening.

3. The housing as claimed in claim 1, wherein, when said controller determines that another one of said walls which is not provided with said fan is on the top of said housing body, said controller is configured to control said fan to operate in an intake mode for drawing air into said housing body to cause the upward airflow within said housing body toward said another one of said walls.

4. The housing as claimed in claim 1, wherein another one of said walls is formed with another opening.

5. The housing as claimed in claim 4, wherein, when said controller determines that said another one of said walls is on the top of said housing body, said controller is configured to control said fan to operate in an intake mode for drawing air into said housing body and for causing the upward airflow within said housing body toward said another one of said walls so that air within said housing body is exhausted through said another opening of said another one of said walls.

6. The housing as claimed in claim 5, further comprising another fan that is mounted to said another one of said walls at said another opening,
wherein said controller is configured to further control said another fan to operate in an exhausting mode for facilitating the upward airflow within said housing body toward said another one of said walls.

7. The housing as claimed in claim 4, further comprising another fan that is mounted to said another one of said walls at said another opening,
wherein, when said controller determines that said one of said walls which is provided with said fan is on the top of said housing body, said controller is configured to
control said fan to operate in an exhausting mode for causing the upward airflow within said housing body toward said one of said walls and for exhausting air in said housing body through said opening, and
control said another fan to operate in an intake mode for drawing air into said housing body.

8. The housing as claimed in claim 1, wherein each of said walls of said housing body is formed with an opening, and said housing comprises a plurality of fans each mounted to a respective one of said walls at said opening,
wherein said controller is configured to control one of said fans that is mounted to one of said walls on the top of said housing body to operate in an exhausting mode for causing the upward airflow within said housing body toward said one of said walls on the top of said housing body and for exhausting air in said housing body through said opening of said one of said walls, and to control the remaining ones of said fans to each operate in an intake mode for drawing air into said housing body.

9. The housing as claimed in claim 1, wherein said orientation detecting unit includes an accelerometer.

10. The housing as claimed in claim 1, wherein said orientation detecting unit includes a switch disposed on one of said walls;
wherein said switch is configured to generate the detection signal when being pressed; and
wherein, when said controller receives the detection signal from said switch, said controller determines that an opposite one of said walls that is opposite to said one of said walls provided with said switch is on the top of said housing body.

11. The housing as claimed in claim 10, wherein said one of said walls that is formed with said opening is said opposite one of said walls,
wherein said controller is configured to control said fan to operate in an exhausting mode for causing the upward airflow within said housing body toward said opposite one of said walls and for exhausting air in said housing body through said opening when said controller receives the detection signal from said switch, and to control said fan to operate in an intake mode for drawing air into said housing body through said opening when otherwise.

12. The housing as claimed in claim 1, wherein said orientation detecting unit includes a plurality of switches disposed on said walls, respectively,
wherein each of said switches is configured to generate the detection signal when being pressed,
wherein, when said controller receives the detection signal from one of said switches that is disposed on a corresponding one of said walls, said controller determines that an opposite one of said walls that is opposite to said corresponding one of said walls is on the top of said housing body.
